(19) United States
(12) Patent Application Publication
(10) Pub. No.: US 2025/0366325 A1
(43) Pub. Date: Nov. 27, 2025

(54) DISPLAY SUBSTRATE, METHOD OF MANUFACTURING THE SAME, AND DISPLAY APPARATUS

(71) Applicants: Wuhan BOE Optoelectronics Technology Co.,Ltd., Wuhan (CN); BOE TECHNOLOGY GROUP CO., LTD., Beijing (CN)

(72) Inventors: Zengjie KONG, Beijing (CN); Yujie GAO, Beijing (CN); Peng JIANG, Beijing (CN); Xin LIU, Beijing (CN); Chenguang GUO, Beijing (CN); Junling HUANG, Beijing (CN); Ming WANG, Beijing (CN); Yazheng QIAO, Beijing (CN); Lu SHEN, Beijing (CN); He LIU, Beijing (CN); Jun DING, Beijing (CN); Baoman LI, Beijing (CN); Wei DAI, Beijing (CN)

(21) Appl. No.: 18/995,616

(22) PCT Filed: May 14, 2024
(86) PCT No.: PCT/CN2024/093182

§ 371 Date: Jan. 16, 2025

(30) Foreign Application Priority Data
Jun. 25, 2023 (CN) 202310755707.2

(51) Int. Cl. H10K 59/131; H10K 59/12; H10K 59/121

(52) U.S. Cl. CPC H10K 59/131; H10K 59/1201; H10K 59/1213

(57) ABSTRACT

A display substrate is provided, including: a base substrate; a first conductive layer, a second conductive layer, a semiconductor layer, a third conductive layer and a passivation layer sequentially arranged on the base substrate along a direction away from the base substrate; and a first electrode via hole penetrating the passivation layer. The second conductive layer, includes a first electrode. The second conductive layer includes a gate electrode. The third conductive layer includes a transfer portion, of which an orthographic projection on the base substrate falls within an orthographic projection of the first electrode on the base. An opening area of the first electrode via hole gradually decreases in a direction pointing towards the base substrate, and an exposed part of the transfer portion by the first electrode via hole serves as a part of a via hole sidewall of the first electrode via hole.

### CROSS-REFERENCE TO RELATED APPLICATION

This application is a Section 371 National Stage Application of International Application No. PCT/CN2024/093182, filed on May 14, 2024, and the PCT Application claims priority to the Chinese Patent Application No. 202310755707.2 filed on Jun. 25, 2023, the whole disclosures of which are incorporated herein by reference in their entireties.

### TECHNICAL FIELD

The present disclosure relates to the field of display technology, and in particular, to a display substrate, a method of manufacturing the same, and a display apparatus.

### BACKGROUND

With the development of display technology, display apparatus are increasingly used in various fields, and the requirements for display technology are becoming increasingly higher. In a manufacturing process of a display apparatus, a plurality of metal wires and a plurality of via holes for connecting the metal wires are arranged in different layers, and by filling a conductive material in the via holes, electrical connections between the metal wires in different layers may be achieved. However, in existing manufacturing processes of via holes, the metal wires in different layers have some impact on the via hole etching process. For example, when a via hole is arranged close to a metal wire, the metal wire collects charged particles generated during the etching process, resulting in a defect at the via hole, which in turn leads to a decrease in the product yield.

### SUMMARY

Embodiments of the present disclosure provide a display substrate, a method of manufacturing the same, and a display apparatus.

In an aspect, a display substrate is provided, including but not limited to: a base substrate, where a plurality of sub-pixels are arranged on the base substrate in an array in a first direction and a second direction, the first direction intersects with the second direction, and each sub-pixel includes at least one control transistor; a first conductive layer arranged on a side of the base substrate, where the first conductive layer includes first electrodes arranged at intervals in the second direction and configured to form the sub-pixel: a second conductive layer arranged on a side of the first conductive layer away from the base substrate, where the second conductive layer includes gate electrodes configured to form the control transistors, where the gate electrodes are arranged at intervals in the second direction and extend in the first direction; a semiconductor layer arranged on a side of the second conductive layer away from the base substrate, where an orthographic projection of the semiconductor layer on the base substrate falls within an orthographic projection of the second conductive layer on the base substrate: a third conductive layer arranged on a side of the semiconductor layer away from the base substrate, where the third conductive layer includes a transfer portion, and an orthographic projection of the transfer portion on the base substrate falls within an orthographic projection of the first electrode on the base substrate: a passivation layer arranged on a side of the third conductive layer away from the base substrate; a first electrode via hole penetrating the passivation layer and exposing a part of the first electrode and a part of the transfer portion, where an opening area of the first electrode via hole gradually decreases in a direction pointing towards the base substrate, and the exposed part of the transfer portion serves as a part of a via hole sidewall of the first electrode via hole; and a fourth conductive layer arranged in the first electrode via hole and electrically connecting the first electrode to the transfer portion.

In some exemplary embodiments of the present disclosure, the via hole sidewall of the first electrode via hole includes a step portion: and the step portion includes: a step top surface, where an exposed surface of the transfer portion on a side away from the base substrate serves as the step top surface: and a step side surface, where an exposed surface of the transfer portion facing an inside of the first electrode via hole serves as the step side surface. An opening area of the first electrode via hole at the step side surface is greater than or equal to an opening area of the first electrode via hole on a side of the step portion close to the base substrate.

In some exemplary embodiments of the present disclosure, a surface roughness of an unexposed surface of the transfer portion on a side away from the base substrate is less than a surface roughness of the step top surface.

In some exemplary embodiments of the present disclosure, an angle between the step top surface of the step portion and the step side surface of the step portion is θ, where 90°<θ<180°.

In some exemplary embodiments of the present disclosure,

the first electrode via hole exposes a part of the semiconductor layer, and the exposed part of the semiconductor layer serves as a part of the via hole sidewall of the first electrode via hole; and an opening area of the first electrode via hole at the semiconductor layer is less than or equal to an opening area of the first electrode via hole at the step portion.

In some exemplary embodiments of the present disclosure, the first electrodes include pixel electrodes arranged at intervals in the first direction, where each pixel electrode corresponds to a respective sub-pixel. The third conductive layer further includes: data signal lines arranged at intervals in the first direction and extending in the second direction: and a first electrode and a second electrode configured to form the control transistor, where the first electrode of the control transistor is electrically connected to the data signal line, and the second electrode of the control transistor is electrically connected to the transfer portion.

In some exemplary embodiments of the present disclosure, the third conductive layer further includes voltage signal lines arranged at intervals in the first direction and extending in the second direction. The voltage signal line is arranged between adjacent data signal lines: and the sub-pixel is arranged between voltage signal line and data signal line adjacent to each other.

In some exemplary embodiments of the present disclosure, the voltage signal line is electrically connected to a common electrode through a second electrode via hole.

In some exemplary embodiments of the present disclosure, the gate electrode is arranged between adjacent pixel electrodes: orthographic projections of the first electrode and the second electrode of the control transistor on the base substrate fall within the orthographic projection of the semiconductor layer on the base substrate, and the orthographic projection of the semiconductor layer on the base substrate falls within an orthographic projection of the gate electrode on the base substrate; and the gate electrode is configured to control transmission of a data signal from the data signal line to the pixel electrode via the control transistor, the transfer portion and the fourth conductive layer.

In some exemplary embodiments of the present disclosure, the sub-pixels include a first sub-pixel and a second sub-pixel adjacent to each other in the first direction, the first sub-pixel and the second sub-pixel are arranged between adjacent data signal lines, and the voltage signal line is arranged between the first sub-pixel and the second sub-pixel: the gate electrodes include a first gate electrode and a second gate electrode adjacent to each other in the second direction: the first gate electrode is configured to control a control transistor of a first sub-pixel close to the first gate electrode; and the second gate electrode is configured to control a control transistor of a second sub-pixel close to the second gate electrode.

In some exemplary embodiments of the present disclosure, the first electrodes include common electrodes, and a side of each common electrode away from the base substrate is provided with a plurality of first electrode via holes: and the third conductive layer further includes a connection portion, and the connection portion electrically connects transfer portions corresponding to common electrodes adjacent to each other in the second direction. The connection portion is configured to electrically connect the common electrodes adjacent to each other in the second direction through the fourth conductive layer arranged in the first electrode via hole and the transfer portion.

In some exemplary embodiments of the present disclosure, the second conductive layer further includes voltage signal lines arranged at intervals in the second direction and extending in the first direction: and the voltage signal line is electrically connected to the common electrode.

In some exemplary embodiments of the present disclosure, the gate electrode is arranged adjacent to the voltage signal line, and the gate electrode and the voltage signal line are arranged between adjacent common electrodes.

In some exemplary embodiments of the present disclosure, the third conductive layer further includes: data signal lines arranged at intervals in the first direction and extending in the second direction; and a first electrode and a second electrode configured to form the control transistor. The first electrode of the control transistor is electrically connected to the data signal line, and the second electrode of the control transistor is electrically connected to a pixel electrode through a third electrode via hole.

In another aspect of the present disclosure, a method of manufacturing a display substrate is provided, including: forming a first conductive layer on a side of a base substrate, where the first conductive layer includes first electrodes arranged at intervals in a second direction and configured to form sub-pixels arranged on the base substrate, the sub-pixels arranged on the base substrate are arranged in an array in a first direction and the second direction, and the first direction intersects with the second direction; forming a second conductive layer on a side of the first conductive layer away from the base substrate, where the second conductive layer includes gate electrodes that are arranged at intervals in the second direction, extend in the first direction and are configured to form control transistors; forming a semiconductor layer on a side of the second conductive layer away from the base substrate, where an orthographic projection of the semiconductor layer on the base substrate falls within an orthographic projection of the second conductive layer on the base substrate: forming a third conductive layer on a side of the semiconductor layer away from the base substrate, where the third conductive layer includes a transfer portion, and an orthographic projection of the transfer portion on the base substrate falls within an orthographic projection of the first electrode on the base substrate; forming a passivation layer on a side of the third conductive layer away from the base substrate: forming a first electrode via hole penetrating the passivation layer and exposing a part of the first electrode and a part of the transfer portion, where an opening area of the first electrode via hole gradually decreases in a direction pointing towards the base substrate, and the exposed part of the transfer portion serves as a part of a via hole sidewall of the first electrode via hole; and forming a fourth conductive layer in the first electrode via hole, where the fourth conductive layer electrically connects the first electrode to the transfer portion.

In some exemplary embodiments of the present disclosure, the forming a first electrode via hole includes: forming a first sub-via hole and a second sub-via hole, where the first sub-via hole exposes a part of the first electrode, and an orthographic projection of the first sub-via hole on the base substrate does not overlap with the orthographic projection of the transfer portion on the base substrate; and the second sub-via hole exposes a part of the transfer portion, and an orthographic projection of the second sub-via hole on the base substrate overlaps with the orthographic projection of the transfer portion on the base substrate.

In some exemplary embodiments of the present disclosure, the forming a first sub-via hole and a second sub-via hole includes: coating a photoresist on a side of the passivation layer away from the base substrate: performing a full-exposure process on a region of the photoresist corresponding to the first sub-via hole, and performing a half-exposure process on a region of the photoresist corresponding to the second sub-via hole; etching a layer material in a region corresponding to the first sub-via hole to expose the first electrode; and etching a layer material in a region corresponding to the second sub-via hole to expose the transfer portion, where the exposed transfer portion is configured to form the via hole sidewall of the first electrode via hole.

In some exemplary embodiments of the present disclosure, the etching a layer material in a region corresponding to the first sub-via hole includes: etching a region of the passivation layer corresponding to the first sub-via hole, and etching a region of an insulating layer corresponding to the first sub-via hole with a first dry etching medium, where the insulating layer is between the passivation layer and the first electrode in the region.

In some exemplary embodiments of the present disclosure, the etching a layer material in a region corresponding to the second sub-via hole includes: etching a material of the photoresist in a region of the second sub-via hole with a second dry etching medium: and etching a material of the passivation layer in the region of the second sub-via hole with a first dry etching medium.

In some exemplary embodiments of the present disclosure, the method further includes: etching a photoresist arranged on an upper side of the passivation layer with a second dry etching medium.

In some exemplary embodiments of the present disclosure, the forming a first sub-via hole and forming a second sub-via hole includes: coating a first photoresist on a side of the passivation layer away from the base substrate: performing a full-exposure process on a region of the first photoresist corresponding to the first sub-via hole: etching a layer material in a region corresponding to the first sub-via hole to expose the first electrode: stripping the first photoresist: coating a second photoresist on a side of the passivation layer away from the base substrate so that a part of the second photoresist is filled in the first sub-via hole; performing a full-exposure process on a region of second photoresist corresponding to the second sub-via hole: etching a layer material in a region corresponding to the second sub-via hole to expose the transfer portion, where the exposed transfer portion is configured to form the via hole sidewall of the first electrode via hole; and stripping the second photoresist.

In yet another aspect of the present disclosure, a display apparatus is provided, including the display substrate described above.

### BRIEF DESCRIPTION OF THE DRAWINGS

Other objectives and advantages of the present disclosure will become more apparent through the following description of the present disclosure with reference to the accompanying drawings, which may assist in a comprehensive understanding of the present disclosure.

FIG. 1 is a schematic plan view of a display substrate according to an exemplary embodiment of the present disclosure.

FIG. 2 is a schematic planar structural diagram of a display substrate according to an embodiment of the present disclosure.

FIG. 3 is a partially enlarged schematic diagram showing a structure in region A of FIG. 2 according to an embodiment of the present disclosure.

FIG. 4 is a schematic cross-sectional diagram of a structure along line B-B′ in FIG. 3 according to an embodiment of the present disclosure.

FIG. 5 is a schematic plan diagram showing a structure of a display substrate according to another embodiment of the present disclosure.

FIG. 6 is a partially enlarged schematic diagram showing a structure in region C of FIG. 5 according to an embodiment of the present disclosure.

FIG. 7 is a flowchart of a method of manufacturing a display substrate according to an exemplary embodiment of the present disclosure.

FIG. 8A to FIG. 8L are schematic cross-sectional structural diagrams during a manufacturing process using a method of manufacturing a display substrate according to an exemplary embodiment of the present disclosure.

FIG. 9A to FIG. 9G are schematic cross-sectional structural diagrams during a manufacturing process using a method of manufacturing a display substrate according to another exemplary embodiment of the present disclosure.

FIG. 10A is a schematic plan view of a first electrode via hole manufactured using a conventional manufacturing method.

FIG. 10B is an actual cross-sectional structural diagram taken along the dashed line in FIG. 10A.

FIG. 10C is a schematic plan view of a first electrode via hole manufactured using a manufacturing method according to an exemplary embodiment of the present disclosure.

FIG. 10D is an actual cross-sectional structural diagram taken along the dashed line in FIG. 10C.

It should be noted that, for the sake of clarity, dimensions of layers, structures or regions in the accompanying drawings used to describe the embodiments of the present disclosure may be exaggerated or reduced, i.e., the drawings are not drawn to an actual scale.

### DETAILED DESCRIPTION OF EMBODIMENTS

The technical solution of the present disclosure is further specifically described below through embodiments and in combination with the accompanying drawings. In the specification, the same or similar reference signs denote the same or similar parts. The following description of embodiments of the present disclosure with reference to the accompanying drawings is intended to explain the general inventive concept of the present disclosure, and should not be construed as limiting the present disclosure.

In addition, in the following detailed descriptions, for purposes of explanation, numerous specific details are set forth in order to provide a thorough understanding of embodiments of the present disclosure. It is obvious, however, that one or more embodiments may be implemented without these specific details.

It should be noted that, although terms “first”, “second”, etc. may be used herein to describe various parts, components, elements, regions, layers and/or sections, these parts, components, elements, regions, layers and/or sections should not be limited by these terms. Rather, these terms are used to distinguish one part, component, element, region, layer or section from another. Thus, for example, a first part, a first component, a first element, a first region, a first layer, and/or a first section discussed below could be termed a second part, a second component, a second element, a second region, a second layer, and/or a second section without departing from teachings of the present disclosure.

For convenience in description, spatial relationship terms, such as “upper”, “lower”, “left”, “right” and the like, may be used herein to describe a relationship between one element or feature and another element or feature as illustrated in the figures. It will be understood that the spatial relationship terms are intended to encompass different orientations of a device in use or operation in addition to an orientation depicted in the figures. For example, if the device in the figures is turned over, elements described as “below” or “beneath” other elements or features would then be oriented “above” or “over” other elements or features.

As used herein, the terms “substantially”, “about”, “approximately”, “roughly”, and other similar terms are used as terms of approximation rather than as terms of degree, and are intended to account for inherent deviations in measured or calculated values that would be recognized by those of ordinary skill in the art. Taking into account factors such as process fluctuations, measurement problems, errors associated with measurement of particular quantities (i.e., limitations of a measurement system), etc., “about” or “approximately” as used herein includes the stated values, and indicates that the particular values are within acceptable tolerances as determined by those of ordinary skill in the art. For example, “about” may mean within one or more standard deviations, or within ±30%, ±20%, ±10%, or ±5% of the stated values.

It should be noted that the expression “a same layer” herein refers to a layer structure formed by forming a layer for forming a specific pattern by using the same film formation process and then patterning the layer by the one-shot patterning process using the same mask. Depending on the specific pattern, the one-shot patterning process may include a plurality of exposure, development or etching processes, and the specific pattern in the formed layer structure may be continuous or discontinuous. That is, a plurality of elements, components, structures and/or sections located in “a same layer” are made of the same material and formed by the same one-shot patterning process, and generally, the plurality of elements, components, structures and/or sections located in “a same layer” have substantially the same thickness.

Those skilled in the art should understand that, unless otherwise specified, the expressions “continuous extension”, “integrated structure”, “integral structure” or similar expressions refer to that a plurality of elements, components, structures and/or sections are located on the same layer and are typically formed through the same one-shot patterning process in the manufacturing process. There are no gaps or breaks between these elements, components, structures and/or sections, but rather a continuously extending structure.

Herein, directional expressions such as “first direction” and “second direction” are used to describe different directions along a pixel region, such as a longitudinal direction and a lateral direction of the pixel region. It should be understood that such expressions are merely illustrative descriptions and are not construed as limiting the present disclosure.

In the present disclosure, the term “control transistor” refers to a transistor in a sub-pixel for controlling the transmission of a data signal to the sub-pixel. In the present disclosure, a sub-pixel may include one or more transistors, which may include one or more control transistors.

In the present disclosure, the term “opening area” refers to an area of an orthographic projection of an opening of the electrode via hole on a plane parallel to the opening of the electrode via hole. As a spacing between a position and the base substrate changes, the opening area of the electrode via hole at different positions varies.

In the related art, display panels may have different display modes, such as an ADS display mode and an iADS display mode, depending on structures of the display panels. Due to the fact that the display panel includes a plurality of different layers, and the layers include a plurality of insulating layers and a plurality of metal wires, even if the structures of the display panels are different, it is necessary to electrically connect metal wires arranged in different layers. Generally, an electrode via hole is manufactured by using an exposure process, so as to electrically connect the metal wires in different layers. However, when the electrode via hole is close to a metal wire, the metal wire is prone to induce a plasma effect during a dry etching process, such that an etching rate of the insulating layer close to the metal is high, which may cause a lot of defects of the electrode via hole and easily lead to defective products. As such, the yield of the product may be reduced, and the display effect of the product may be reduced.

In order to solve the above-mentioned problems, the embodiments of the present disclosure provide a display substrate, including but not limited to: a base substrate, where a plurality of sub-pixels are arranged on the base substrate in an array in a first direction and a second direction, the first direction intersects with the second direction, and each sub-pixel includes at least one control transistor: a first conductive layer arranged on a side of the base substrate, where the first conductive layer includes first electrodes arranged at intervals in the second direction and configured to form the sub-pixels: a second conductive layer arranged on a side of the first conductive layer away from the base substrate, where the second conductive layer includes gate electrodes arranged at intervals in the second direction, extending in the first direction and configured to form the control transistors: a semiconductor layer arranged on a side of the second conductive layer away from the base substrate, where an orthographic projection of the semiconductor layer on the base substrate falls within an orthographic projection of the second conductive layer on the base substrate: a third conductive layer arranged on a side of the semiconductor layer away from the base substrate, where the third conductive layer includes a transfer portion, and an orthographic projection of the transfer portion on the base substrate falls within an orthographic projection of the first electrode on the base substrate: a passivation layer arranged on a side of the third conductive layer away from the base substrate: a first electrode via hole penetrating the passivation layer and exposing a part of the first electrode and a part of the transfer portion, where an opening area of the first electrode via hole gradually decreases in a direction pointing towards the base substrate, and the exposed part of the transfer portion serves as a part of a via hole sidewall of the first electrode via hole: and a fourth conductive layer arranged in the first electrode via hole and electrically connecting the first electrode to the transfer portion.

According to the embodiments of the present disclosure, the first electrode via hole penetrates the passivation layer and exposes a part of the first electrode and a part of the transfer portion in the third conductive layer, so that the first electrode may be electrically connected with the transfer portion. By configuring the opening area of the first electrode via hole to gradually decrease in the direction pointing towards the base substrate, it is possible to prevent defects of the exposed transfer portion from in the subsequent manufacturing process, thereby improving the yield of the display substrate and the display effect of the display substrate.

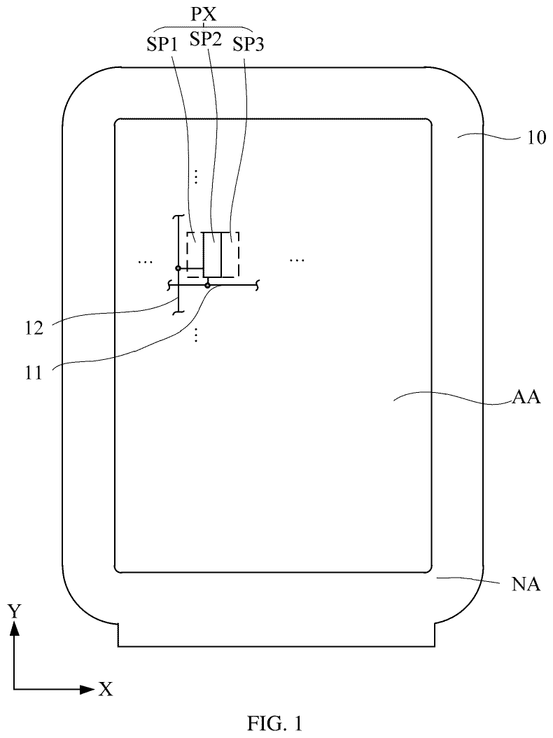

The structure of the display substrate according to the embodiments of the present disclosure will be described in details below with reference to FIG. 1 to FIG. 8L.

FIG. 1 is a schematic plan view of a display substrate according to an exemplary embodiment of the present disclosure. Referring to FIG. 1, the display substrate according to the embodiments of the present disclosure may include a base substrate 10 and pixel units PX arranged on the base substrate 10.

The display substrate may include a display area AA and a non-display area NA. The display area AA may be an area where the pixel units PX for displaying an image are arranged. The pixel unit PX will be described later. The non-display area NA is an area where the pixel unit PX is not arranged, that is, the non-display area NA may be an area not used to display images. The non-display area NA corresponds to the frame of a display apparatus, and a width of the frame may be determined based on a width of the non-display area NA.

The display area AA may have various shapes. For example, the display area AA may be set in various shapes such as a polygon (for example, a rectangle) having a closed shape including a straight edge, a circle and an ellipse including a curved edge, and the like, and a semicircle and a semi-ellipse including a straight edge and a curved edge, and the like. In the embodiments of the present disclosure, the display area AA is set as an area having a quadrilateral shape including straight edges. It will be understood that this is only an exemplary embodiment of the present disclosure and is not a limitation to the present disclosure.

The non-display area NA may be arranged on at least one side of the display area AA. In the embodiments of the present disclosure, the non-display area NA may surround an outer periphery of the display area AA. In the embodiments of the present disclosure, the non-display area NA may include a lateral portion extending in a first direction X and a longitudinal portion extending in a second direction Y.

The pixel units PX are arranged in the display area AA. The pixel unit PX is a minimum unit for displaying an image, and a plurality of pixel units PX may be provided. For example, the pixel unit PX may include a light-emitting device that emits white light and/or colored light.

A plurality of pixel units PX may be arranged in a matrix with rows extending in the first direction X and columns extending in the second direction Y. However, the embodiments of the present disclosure do not particularly limit the arrangement form of the pixel units PX, and the pixel units PX may be arranged in various forms. For example, the pixel unit PX may be arranged such that a direction tilted relative to the first direction X and the second direction Y is a column direction, and a direction intersecting with the column direction is a row direction.

That is, the plurality of pixel units PX are arranged in an array in the first direction X and the second direction Y, so as to form a plurality of rows of pixel units and a plurality of columns of pixel units.

The pixel unit PX may include a plurality of sub-pixels. For example, the pixel unit PX may include three sub-pixels, i.e., a first sub-pixel SP1, a second sub-pixel SP2, and a third sub-pixel SP3. For example, the first sub-pixel SP1 may be a red sub-pixel, the second sub-pixel SP2 may be a green sub-pixel, and the third sub-pixel SP3 may be a blue sub-pixel.

It will be noted that in the embodiments of the present disclosure, the number of the sub-pixels in one pixel unit is not particularly limited, and is not limited to the three described above.

For example, in the exemplary embodiment shown in FIG. 1, a signal line 11 and a data line 12 are schematically shown. The display substrate may further include a plurality of signal lines 11 and a plurality of data lines 12 arranged on the base substrate, where the plurality of signal lines 11 supply, for example, scanning control signals to the plurality of rows of pixel units respectively, and the plurality of data lines 12 supply data signals to the plurality of columns of pixel units respectively. The signal line 11 extends in the first direction X, and the plurality of signal lines 11 are arranged at intervals in the second direction Y. The data line 12 extends in the second direction Y, and the plurality of data lines 12 are arranged in the first direction X.

For example, the lateral wire may represent a signal line 11, and a longitudinal wire may represent a data line 12. It will be understood that the lateral wire may further include other types of wires or wires for supplying other signals, and the longitudinal wire may further include other types of wires or wires for supplying other signals.

Each sub-pixel may include a light-emitting element and a pixel driving circuit for driving the light-emitting element. For example, in an OLED display substrate or a display panel, the light-emitting element of the sub-pixel may include an anode, a light-emitting material layer and a cathode arranged in a stack. The anodes of the light emitting elements of the respective sub-pixels are arranged at intervals in a matrix with rows extending in the first direction X and columns extending in the second direction Y.

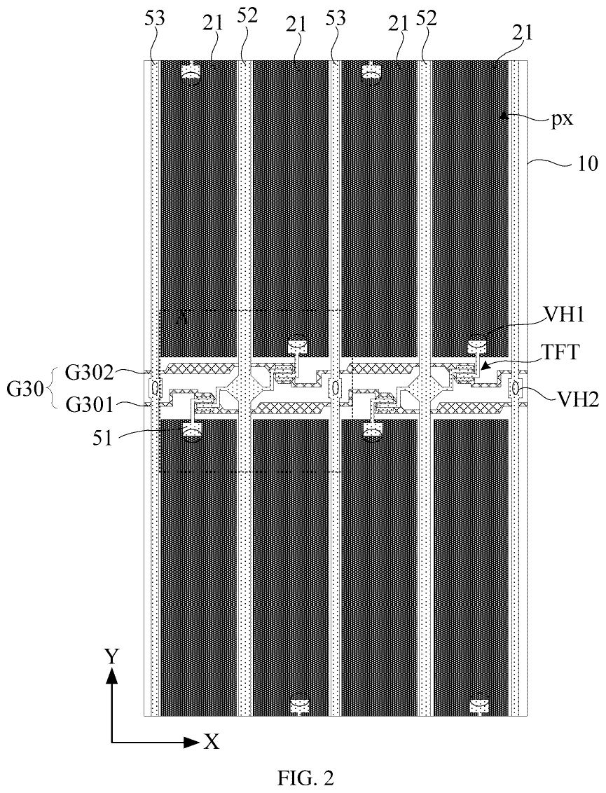

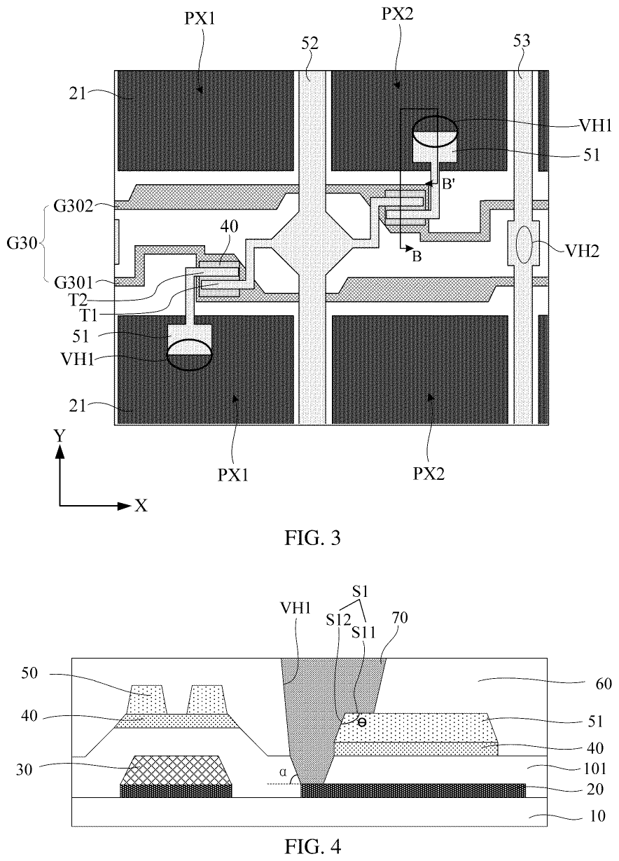

FIG. 2 is a schematic planar structural diagram of a display substrate according to an embodiment of the present disclosure. FIG. 3 is a partially enlarged schematic diagram showing a structure in region A of FIG. 2 according to an embodiment of the present disclosure. FIG. 4 is a schematic cross-sectional diagram of a structure along line B-B′ in FIG. 3 according to an embodiment of the present disclosure.

The structure of the display substrate according to the embodiments of the present disclosure will be described in details below with reference to FIG. 2 to FIG. 4.

As shown in FIG. 2 to FIG. 4, the display substrate 100 includes a base substrate 10, a first conductive layer 20, a second conductive layer 30, a semiconductor layer 40, a third conductive layer 50, a passivation layer 60, and a fourth conductive layer 70.

As shown in FIG. 2, a plurality of sub-pixels px are arranged on the base substrate 10 in an array in the first direction X and the second direction Y. The first direction X intersects with the second direction Y, and each sub-pixel px includes at least one control transistor TFT.

For example, the sub-pixels arranged in an array may emit light of different colors. For example, three sub-pixels may also be referred to as a pixel unit. The first direction X refers to, for example, a lateral direction of the display substrate, and the second direction Y refers to, for example, a longitudinal direction perpendicular to the lateral direction of the display substrate. In an optional embodiment, the first direction X and the second direction Y may be set to have a certain angle therebetween, so as to achieve different pixel arrangements and display effects.

The control transistor TFT may refer to one of the one or more transistors in each sub-pixel for implementing a specific control function. For example, the control transistor TFT of each sub-pixel is configured to control transmission of a data signal to a pixel electrode of the sub-pixel.

As shown in FIG. 4, the first conductive layer 20 is arranged on a side of the base substrate 10, and the first conductive layer 20 includes first electrodes arranged at intervals in the second direction and configured to form the sub-pixels. In this embodiment, the first electrodes include pixel electrodes 21, and each pixel electrode 21 corresponds to a respective sub-pixel. That is, the pixel electrodes 21 are arranged at intervals in both the first direction X and the second direction Y. For example, the pixel electrodes 21 have a rectangular shape, and a length direction of the rectangle is parallel to the second direction Y. In other alternative embodiments, the first electrodes may further include common electrodes, which will be described in detail below.

The second conductive layer 30 is arranged on a side of the first conductive layer 20 away from the base substrate. The second conductive layer 30 includes gate electrodes G30 arranged at intervals in the second direction Y and extending in the first direction X, which are configured to form the control transistors TFT.

In some embodiments, an orthographic projection of the first conductive layer 20 on the base substrate may overlap with an orthographic projection of the gate electrode G30 on the base substrate, and the part of the first conductive layer 20 overlapping with the gate electrode G30 is insulated from the pixel electrode 21 in the first conductive layer 20, that is, the part of the first conductive layer 20 overlapping with the gate electrode G30 is not electrically connected with the pixel electrode 21 in the first conductive layer 20.

As shown in FIG. 4, the semiconductor layer 40 is arranged on a side of the second conductive layer 30 away from the base substrate 10, and an orthographic projection of the semiconductor layer 40 on the base substrate falls within an orthographic projection of the second conductive layer 30 on the base substrate. Specifically, the orthographic projection of the semiconductor layer 40 on the base substrate overlaps with an orthographic projection of the gate electrode G30 of the second conductive layer 30 on the base substrate, that is, the conduction of the semiconductor layer 40 is controlled through the gate electrode G30.

As shown in FIG. 4, the third conductive layer 50 is arranged on a side of the semiconductor layer 40 away from the base substrate 10, and the third conductive layer 50 includes a transfer portion 51, where an orthographic projection of the transfer portion 51 on the base substrate 10 falls within an orthographic projection of the first electrode on the base substrate.

When the third conductive layer 50 is formed on the side of the semiconductor layer 40 away from the base substrate 10, a part of the formed third conductive layer 50 serves as the transfer portion 51, and other parts of the third conductive layer 50 may be a data signal line, a voltage signal line and the like, which will be described in detail below.

As shown in FIG. 4, the passivation layer 60 is arranged on a side of the third conductive layer 50 away from the base substrate 10. A first electrode via hole VH1 penetrates the passivation layer 60 and exposes a part of the first electrode 21 and a part of the transfer portion 51. An opening area of the first electrode via hole VH1 gradually decreases in a direction pointing towards the base substrate 10. The exposed part of the transfer portion 51 serves as a part of a via hole sidewall of the first electrode via hole. The fourth conductive layer 70 is arranged in the first electrode via hole VH1, and electrically connects the first electrode 21 to the transfer portion 51.

In some embodiments of the present disclosure, one or more insulating layers are provided between the first conductive layer 20 and the semiconductor layer 40, and one or more insulating layers are provided between the second conductive layer 30 and the semiconductor layer 40. For example, the insulating layer(s) may include a gate insulating layer 101.

As shown in FIG. 3 and FIG. 4, a semiconductor layer 40 is further provided between the transfer portion 51 in the third conductive layer 50 and the first electrode 21. In some optional embodiments, no semiconductor layer may be provided between the transfer portion in the third conductive layer and the first electrode.

For example, the first electrode via hole VH1 penetrates the passivation layer 60 and the gate insulating layer 101.

As shown in FIG. 4, the opening area of the first electrode via hole VH1 refers to an area of an orthographic projection of the opening of the first electrode via hole on a plane parallel to an upper surface of the base substrate. The first electrode via hole VH1 has a via hole sidewall that is jointly formed by the passivation layer 60, the transfer portion 51 in the third conductive layer 50, the semiconductor layer 40, and the gate insulating layer 101. The exposed part of the pixel electrode 21 serves as a bottom wall of the first electrode via hole VH1, and the exposed part of the transfer portion 51 serves as a part of the via hole sidewall of the first electrode via hole VH1.

The fourth conductive layer 70 located in the first electrode via hole VH1 is electrically connected to both the exposed part of the transfer portion 51 in the first electrode via hole VH1 and the exposed part of the pixel electrode 21 in the electrode via hole VH1, so that the fourth conductive layer 70 may electrically connect the pixel electrode 21 in the first electrode to the transfer portion 51.

As shown in FIG. 4, the via hole sidewall of the first electrode via hole VH1 includes a step portion S1, and the step portion S1 includes a step top surface S11 and a step side surface S12.

The exposed surface of the transfer portion 51 on a side away from the base substrate 10 serves as the step top surface S11. The exposed surface of the transfer portion 51 facing the inside of the first electrode via hole serves as the step side surface S12. An opening area of the first electrode via hole at the step side surface S12 is greater than or equal to an opening area of the first electrode via hole on a side of the step portion S1 close to the base substrate.

That is, the closer to the base substrate, the smaller the opening area of the first electrode via hole at the step portion of the first electrode via hole VH1. For example, an opening area of the first electrode via hole at the step top surface S11 is greater than the opening area of the first electrode via hole at the step side surface S12, and the opening area of the first electrode via hole at the step side surface S12 is greater than an opening area of the first electrode via hole at a position closer to the base substrate than the step portion S1.

According to the embodiments of the present disclosure, the opening area of the first electrode via hole VH1 gradually decreases in the direction pointing towards the base substrate, so that it is possible to prevent the formation of a gap on a side of the transfer portion close to the base substrate, thus the problem of reduced product yield caused by stripping liquid remaining in the gap during the manufacturing process may be solved, and the display effect of the display substrate may be improved.

In the embodiments of the present disclosure, the transfer portion 51 in the first electrode via hole VH1 includes an exposed part and an unexposed part. The first electrode via hole VH1 is formed by dry etching, and during the etching process, the surface of the transfer portion 51 on a side away from the base substrate 10 is bombarded by plasma and thus has a large surface roughness, while the unexposed part is not bombarded by the plasma and thus is not affected. That is, a surface roughness of the unexposed surface of the transfer portion 51 on the side away from the base substrate is less than a surface roughness of the step top surface.

As shown in FIG. 4, an angle between the step top surface S11 of the step portion and the step side surface S12 of the step portion is θ, where 90°<θ<180°. A certain angle is between the step top surface S11 and the step side surface S12, so that the opening area of the first electrode via hole VH1 may gradually decrease in the direction pointing towards the base substrate.

In some embodiments, a semiconductor layer 40 is further provided on a side of the transfer portion 51 close to the base substrate 10, and the first electrode via hole VH1 exposes a part of the semiconductor layer 40. The exposed semiconductor layer 40 serves as a part of the via hole sidewall of the first electrode via hole VH1. An opening area of the first electrode via hole at the exposed part of the semiconductor layer 40 is less than or equal to the opening area of the first electrode via hole at the step portion S12.

In the embodiments shown in FIG. 2 to FIG. 4, the first electrode includes a pixel electrode, which provides a data signal to a respective sub-pixel.

As shown in FIG. 2 to FIG. 3, the third conductive layer 50 includes data signal lines 52 and voltage signal lines 53.

The data signal lines 52 are arranged at intervals in the first direction X and extend in the second direction Y, and the data signal line 52 is configured to transmit a data signal VDD. The voltage signal lines 53 are arranged at intervals in the first direction X and extend in the second direction Y, and the voltage signal line 53 is configured to transmit a voltage signal Vcom.

The third conductive layer 50 includes a first electrode T1 and a second electrode T2 configured to form the control transistor TFT. The first electrode T1 is electrically connected to the data signal line 52, and the second electrode T2 is electrically connected to the transfer portion 51.

One or more sub-pixels are arranged between data signal lines 52, for example, two sub-pixels are arranged between the data signal lines 52, and one sub-pixel is arranged on each of the both sides of the data signal line 52.

The voltage signal line 53 is arranged between adjacent data signal lines 52, i.e., exhibiting an arrangement in which a voltage signal line 53, a data signal line 52, a voltage signal line 53 and a data signal line 52 are sequentially arranged at intervals.

A second electrode via hole VH2 is arranged at a position where the voltage signal line 53 is located at an interval between the pixel electrodes 21, and the voltage signal line 53 is electrically connected to the common electrode through the second electrode via hole VH2.

As shown in FIG. 2 and FIG. 3, the gate electrode G30 is arranged between adjacent pixel electrodes 21 and extends in the first direction.

As shown in FIG. 3, an orthographic projection of the first electrode T1 and the second electrode T2 on the base substrate 10 falls within an orthographic projection of the semiconductor layer 40 on the base substrate 10, and the first electrode T1 and the second electrode T2 of the semiconductor are electrically connected to the semiconductor layer 40. The orthographic projection of the semiconductor layer 40 on the base substrate 10 falls within an orthographic projection of the gate electrode G30 on the base substrate 10, and the gate electrode G30 is insulated from the semiconductor layer 40 through the gate insulating layer 101. By such orthographic projection relationship between the gate electrode G30 and the semiconductor layer 40, the control by the gate electrode G30 over the semiconductor layer of the control transistor TFT may be achieved.

For example, the gate electrode G30 is configured to control the transmission of the data signal from the data signal line 52 to the pixel electrode 21 via the control transistor TFT, the transfer portion 51 and the fourth conductive layer 70.

In some embodiments of the present disclosure, as shown in FIG. 2 and FIG. 3, the sub-pixels include a first sub-pixel PX1 and a second sub-pixel PX2 adjacent to each other in the first direction X. The first sub-pixel PX1 and the second sub-pixel PX2 are arranged between adjacent data signal lines 52, and the voltage signal line 53 is arranged between the first sub-pixel PX1 and the second sub-pixel PX2.

The gate electrodes G30 include a first gate electrode G301 and a second gate electrode G302, and the first gate electrode G301 and the second gate electrode G302 are adjacent to each other in the second direction Y. The first gate electrode G301 is configured to control the control transistor of the first sub-pixel PX1 close to the first gate electrode G301. The second gate electrode G302 is configured to control the control transistor of the second sub-pixel PX2 close to the second gate electrode G302.

For example, as shown in FIG. 3, the data signal line 52 provides the data signal for the second sub-pixel PX2 on an upper side and the first sub-pixel PX1 on the lower side. Specifically, the data signal line 52 is electrically connected to each of the first electrode T1 of the control transistor TFT in the second sub-pixel PX2 on the upper side and the first electrode T1 of the control transistor TFT in the first sub-pixel PX1 on the lower side. The first gate electrode G301 controls a turned-on state of the control transistor of the first sub-pixel PX1 on the lower side, and the second gate electrode G302 controls a turned-on state of the control transistor of the second sub-pixel PX2 on the upper side.

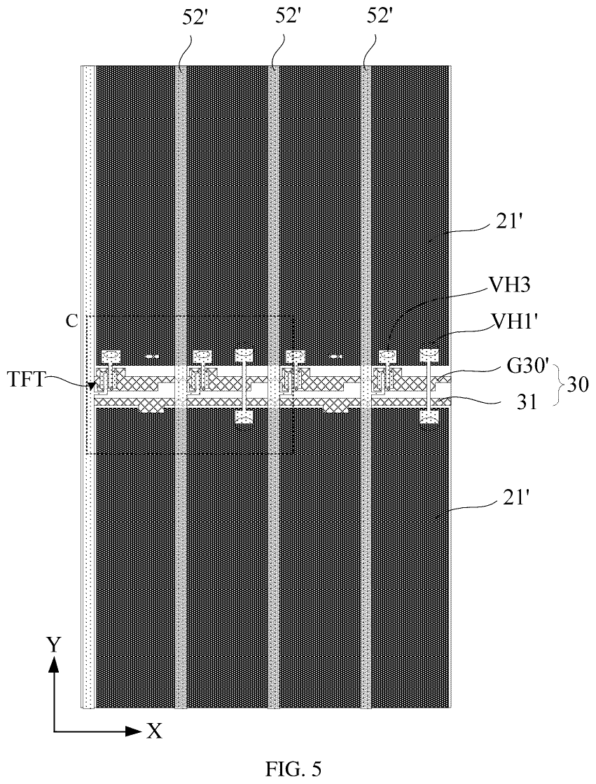

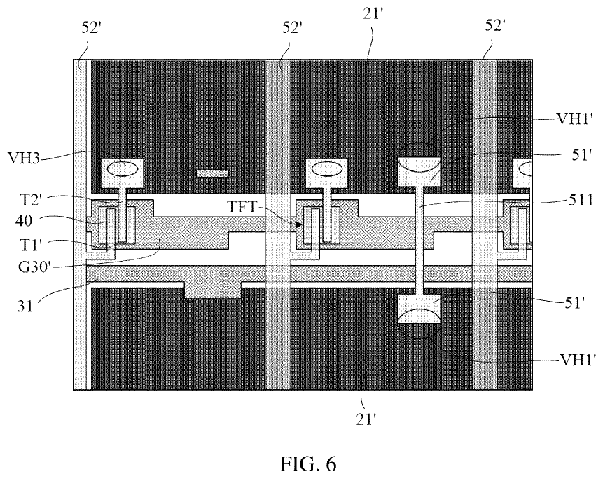

FIG. 5 is a schematic plan diagram showing a structure of a display substrate according to another embodiment of the present disclosure. FIG. 6 is a partially enlarged schematic diagram showing a structure in region C of FIG. 5 according to an embodiment of the present disclosure.

As shown in FIG. 5 and FIG. 6, the first electrodes include common electrodes 21′ of the sub-pixels, and a plurality of first electrode via holes VH1′ are provided on a side of each common electrode 21′ away from the base substrate 10.

For example, a column of sub-pixels arranged in the first direction X may share one common electrode 21′, and the common electrodes 21′ are arranged at intervals in the second direction Y. A second conductive layer 30, which includes a gate electrode G30′ and a voltage signal line 31, is provided between adjacent common electrodes 21′ in the second direction Y. Voltage signal lines 31 are arranged at intervals in the second direction Y and extend in the first direction X, and the voltage signal line is electrically connected to the common electrode 21′. The voltage signal line 31 is configured to transmit a voltage signal Vcom to the common electrode 21′.

A part of the third conductive layer corresponding to a part of an orthographic projection of the third conductive layer 50 on the base substrate 10 within an orthographic projection of the common electrode 21′ on the base substrate 10 is a transfer portion 51′. Each common electrode corresponds to a plurality of transfer portions 51′, and the transfer portion 51′ is configured to electrically connect common electrodes adjacent to each other in the second direction Y. For example, the common electrodes adjacent to each other in the second direction each have a transfer portion 51′ at a respective position, where the transfer portion 51′ is electrically connected to the common electrode 21′ through the fourth conductive layer in the first electrode via hole VH1′. Adjacent transfer portions 51′ are connected to each other through a connection portion.

For example, the third conductive layer further includes a connection portion 511, which electrically connects the transfer portions 51′ corresponding to the common electrodes adjacent to each other in the second direction Y. The connection portion 511 is configured to electrically connect the common electrodes 21′ adjacent to each other in the second direction Y through the fourth conductive layer 70 arranged in the first electrode via hole VH1′ and the transfer portion 51′.

The gate electrode G30′ is arranged adjacent to the voltage signal line 31, and the gate electrode G30′ and the voltage signal line 31 are arranged between adjacent common electrodes 21′.

In the embodiments of the present disclosure, the voltage signal line 31 is electrically connected to the common electrode 21′ to provide a voltage signal to the common electrode. Since the common electrodes 21′ are spaced apart from each other in the second direction Y, there is a voltage difference between the spaced apart common electrodes 21′ due to the resistance and the like, which is prone to cause display non-uniformity of the display substrate during display. By providing the connection portion 511, the common electrodes 21′ arranged at intervals in the second direction may be electrically connected through the transfer portion 51′ and the fourth conductive layer 70 in the first electrode via hole VH1′, so that it is possible to avoid the voltage difference between the common electrodes due to the resistance and other problems, thereby improving the display uniformity of the display substrate and improving the display effect.

As shown in FIG. 6, the third conductive layer 50 further includes data signal lines 52′ arranged at intervals in the first direction X and extending in the second direction Y. The third conductive layer 50 further includes a first electrode T1′ and a second electrode T2′ that are configured to form the control transistor TFT.

The first electrode T1′ of the control transistor TFT is electrically connected to the data signal line 52′, and the second electrode T2′ of the control transistor TFT is electrically connected to a pixel electrode through a third electrode via hole VH3.

In the embodiments of the present disclosure, the second electrode via hole VH2 and the third electrode via hole VH3 are via holes different from the first electrode via hole VH1, and no metal-containing layer is exposed on via hole sidewalls of the second electrode via hole VH2 and the third electrode via hole VH3.

In the embodiments of the present disclosure, as shown in FIG. 4, the opening area of the first electrode via hole VH1 gradually decreases in a direction pointing towards the base substrate. For example, an opening area of the first electrode via hole in the passivation layer 60 is greater than an opening area of the first electrode via hole in the gate insulating layer 101.

For example, an orthographic projection of the opening of the first electrode via hole in the gate insulating layer 101 on the base substrate falls within an orthographic projection of the opening of the first electrode via hole in the passivation layer 60 on the base substrate.

The first electrode via hole VH1 includes via hole sidewalls formed by a passivation layer 60 and a gate insulating layer 101. An angle between lines of a cross-section of the via hole sidewalls formed by the passivation layer 60 and the gate insulating layer 101 is an obtuse angle. That is, there are via hole sidewalls with different angles formed due to different etching rates of the passivation layer 60 and the gate insulating layer 101. For example, the via hole sidewall formed by the gate insulating layer 101 has an angle α with respective to the upper surface of the base substrate, and 35°≤α≤45°. Compared to a process of forming a first electrode via hole through a single exposure process, the present disclosure adopts a formation process of the first electrode via hole in which the first sub-via hole and the second sub-via hole are sequentially formed, and for details, which may be referred to the description of a manufacturing method of the display substrate below for details. In this way, it is possible to avoid formation of a step at the surface of the gate insulating layer on the side away from the base substrate due to the different etching rates of the passivation layer and the gate insulating layer during the process of forming the first electrode via hole through a single exposure. That is, when the first electrode via hole is formed using the manufacturing process according to the present disclosure, there is a transition of a fold line with an obtuse-angle at the joint between the passivation layer and the gate insulating layer, but no platform of a step.

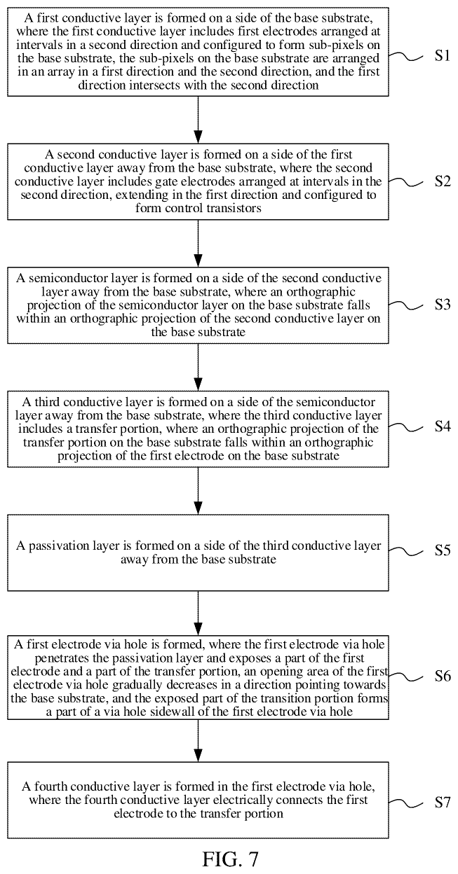

FIG. 7 is a flowchart of a method of manufacturing a display substrate according to an exemplary embodiment of the present disclosure.

As shown in FIG. 7, the method of manufacturing a display substrate includes operation S1 to operation S7.

In operation S1, a first conductive layer is formed on a side of a base substrate, where the first conductive layer includes first electrodes arranged at intervals in a second direction and configured to form sub-pixels on the base substrate, the sub-pixels on the base substrate are arranged in an array in a first direction and the second direction, and the first direction intersects with the second direction intersect.

In operation S2, a second conductive layer is formed on a side of the first conductive layer away from the base substrate, where the second conductive layer includes gate electrodes that are arranged at intervals in the second direction, extend in the first direction and are configured to form control transistors.

In operation S3, a semiconductor layer is formed on a side of the second conductive layer away from the base substrate, where an orthographic projection of the semiconductor layer on the base substrate falls within an orthographic projection of the second conductive layer on the base substrate.

In operation S4, a third conductive layer is formed on a side of the semiconductor layer away from the base substrate, where the third conductive layer includes a transfer portion, and an orthographic projection of the transfer portion on the base substrate falls within an orthographic projection of the first electrode on the base substrate.

In operation S5, a passivation layer is formed on a side of the third conductive layer away from the base substrate.

In operation S6, a first electrode via hole is formed, where the first electrode via hole penetrates the passivation layer and exposes a part of the first electrode and a part of the transfer portion, an opening area of the first electrode via hole gradually decreases in a direction pointing towards the base substrate, and the exposed part of the transfer portion serves as a part of a via hole sidewall of the first electrode via hole.

In operation S7, a fourth conductive layer is formed in the first electrode via hole, where the fourth conductive layer electrically connects the first electrode to the transfer portion.

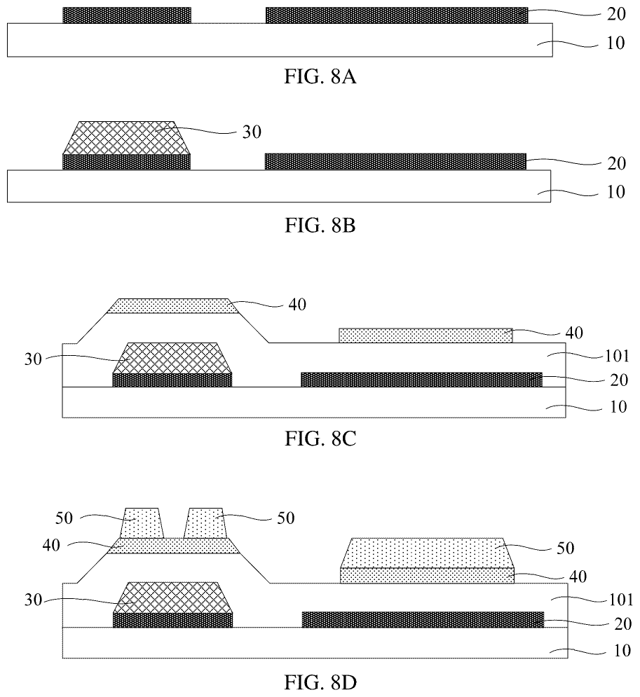

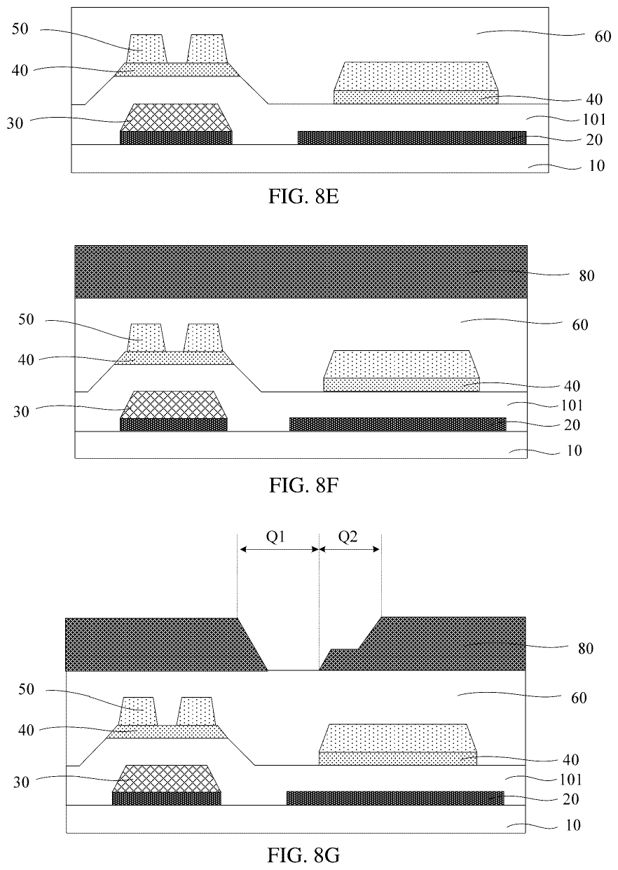

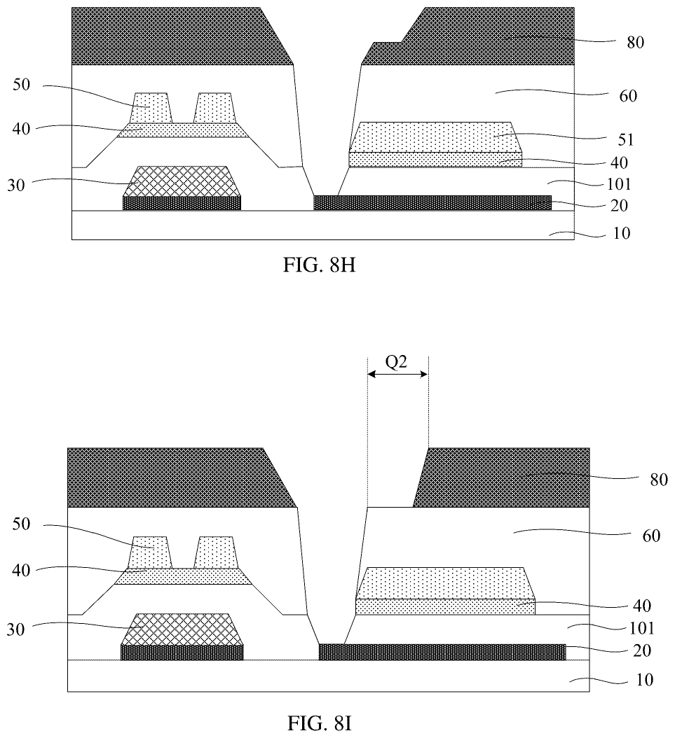

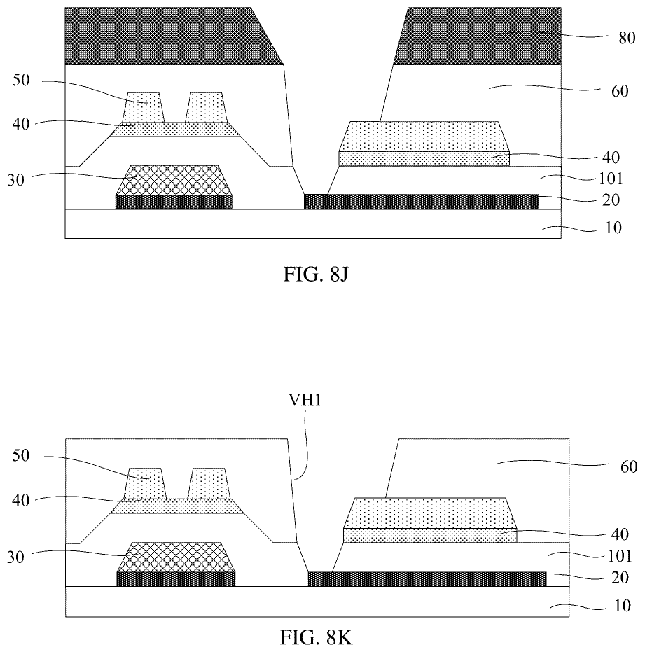

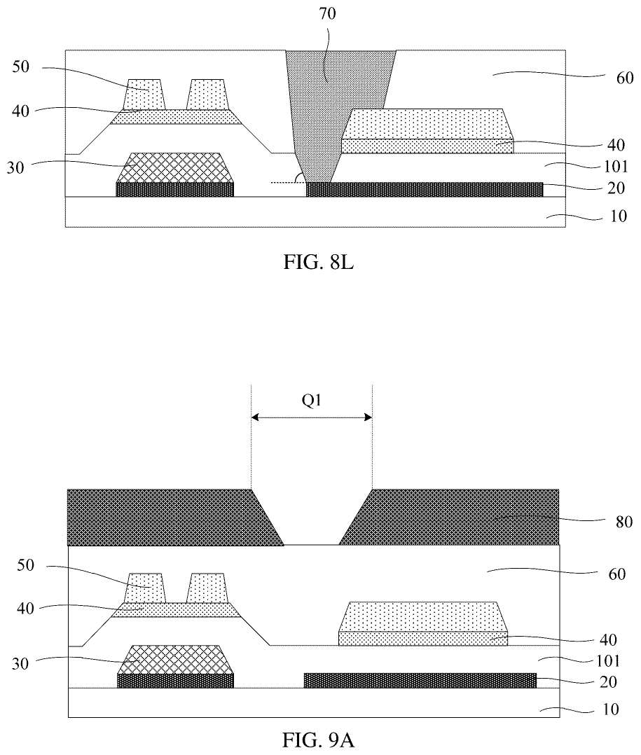

FIG. 8A to FIG. 8L are schematic cross-sectional structural diagrams during a manufacturing process using a method of manufacturing a display substrate according to an exemplary embodiment of the present disclosure.

The method of manufacturing the display substrate according to the embodiments of the present disclosure will be described in detail below with reference to FIG. 8A to FIG. 8L.

As shown in FIG. 8A, a first conductive layer 20 is formed on a side of a display substrate 10, and the formed first conductive layer 20 includes first electrodes arranged at intervals in the second direction and configured to form sub-pixels on the base substrate. The first electrode may be a pixel electrode or a common electrode.

As shown in FIG. 8B, a second conductive layer 30 is formed on a side of the first conductive layer 20 away from the base substrate 10, where the second conductive layer 30 includes gate electrodes arranged at intervals in the second direction, extending in the first direction and configured to form a control transistor.

As shown in FIG. 8C, a gate insulating layer 101 is then formed on the second conductive layer 20, and a semiconductor layer 40 is formed on a side of the gate insulating layer 101 away from the base substrate 10. The semiconductor layer 40 includes a part of which an orthographic projection on the base substrate overlaps with an orthographic projection of the second conductive layer 30 configured to form the gate electrodes on the base substrate, and this part serves as an active layer of the control transistor.

As shown in FIG. 8D, a third conductive layer 50 is formed on a side of the semiconductor layer 40 away from the base substrate 10, where the third conductive layer 50 includes a transfer portion 51, where an orthographic projection of the transfer portion 51 on the base substrate 10 falls within an orthographic projection of the first electrode on the base substrate, that is, the transfer portion 51 is a part of the third conductive layer 50.

As shown in FIG. 8E, a passivation layer 60 is formed on a side of the third conductive layer 50 away from the base substrate 10.

Next, a first electrode via hole is formed, which includes: forming a first sub-via hole and forming a second sub-via hole. The first sub-via hole exposes a part of the first electrode, and an orthographic projection of the first sub-via hole on the base substrate does not overlap with the orthographic projection of the transfer portion on the base substrate. The second sub-via hole exposes a part of the transfer portion, and an orthographic projection of the second sub-via hole on the base substrate overlaps with the orthographic projection of the transfer portion on the base substrate.

As shown in FIG. 8F, a photoresist 80 is first coated on the passivation layer 60.

As shown in FIG. 8G, a segment exposure process is performed on the coated photoresist 80, a full-exposure process is performed on a region of the photoresist corresponding to the first sub-via hole, and a half-exposure process is performed on a region of the photoresist corresponding to the second sub-via hole.

For example, a region Q1 is exposed using a full-exposure process, and a region Q2 is exposed using a half-exposure process. The region Q1 is the region of the photoresist region corresponding to the first sub-via hole, and the region Q2 is the region of the photoresist region corresponding to the second sub-via hole. Thus, a photoresist layer as shown in FIG. 8G is formed.

As shown in FIG. 8H, the layer material in a region corresponding to the first sub-via hole is etched to expose the first electrode in the first conductive layer 20. A region of the passivation layer corresponding to the first sub-via hole and a region of the insulating layer corresponding to the first sub-via hole are etched with a first dry etching medium, where the insulating layer is arranged between the passivation layer and the first electrode.

For example, a dry etching process is adopted, and a first etching medium, such as N₂, is used as the etching medium to etch the passivation layer material and the gate insulating layer material in the first sub-via hole region, so as to expose the first electrode in the first conductive layer 20 to form the bottom wall of the first sub-via hole.

As shown in FIG. 8I, the photoresist material corresponding to the second sub-via hole region is etched, for example, a dry etching process is adopted, and a second etching medium, such as O₂, is used as the etching medium to etch away the photoresist material corresponding to the second sub hole region.

As shown in FIG. 8J, the passivation layer material corresponding to the second sub hole region is then etched with the first dry etching medium. For example, O₂ is used to etch away the passivation layer material corresponding to the second sub-via hole region, so as to expose the transfer portion 51 in the third conductive layer.

As shown in FIG. 8K, a photoresist 80 on an upper side of the passivation layer is etched with a second dry etching medium, so as to form the first electrode via hole VH1, which is convenient for subsequent processes.

In the embodiments of the present disclosure, etching the photoresist on the upper side of the passivation layer with the second dry etching medium may save a wet photoresist stripping process, which may simplify production steps and improve the production efficiency. In addition, the problem of excessive corrosion of the via hole caused by the etching solution remaining in the first electrode via hole may be solved.

In another embodiment of the present disclosure, the photoresist 80 on the upper side of the passivation layer 60 may be stripped using a wet stripping process.

As shown in FIG. 8L, a fourth conductive layer material 70 is then formed in the first electrode via hole VH1, and the fourth conductive layer material electrically connects the first electrode to the transfer portion 51 in the third conductive layer.

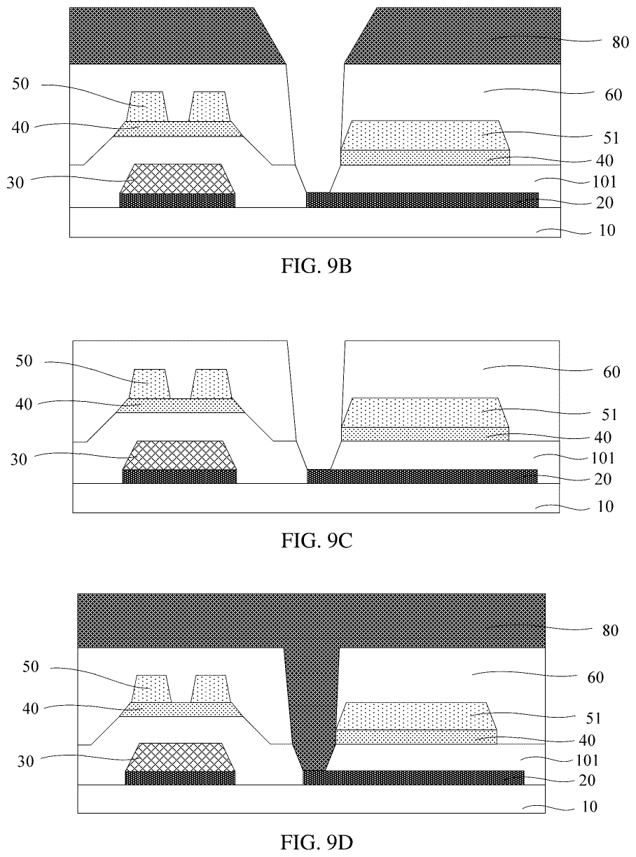

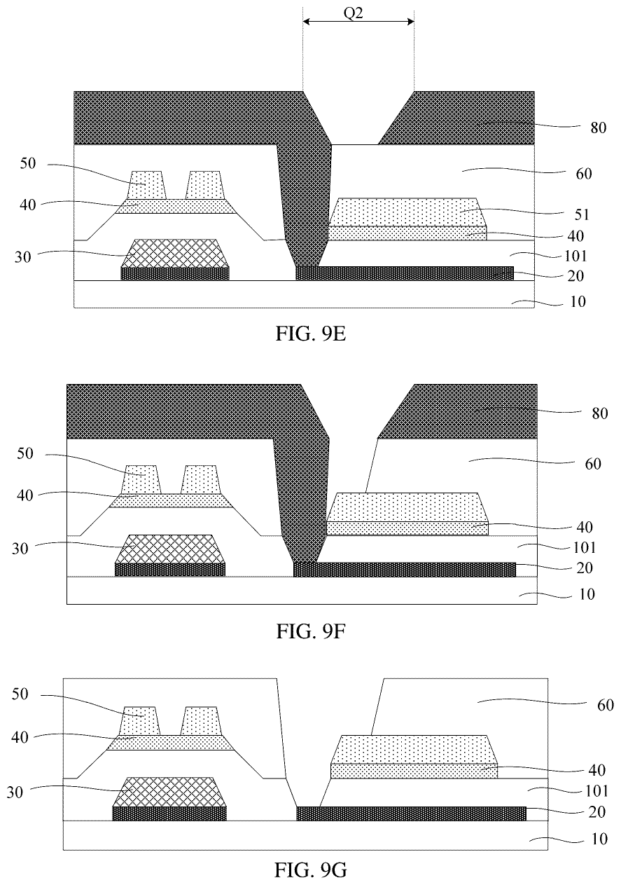

FIG. 9A to FIG. 9G are schematic cross-sectional structural diagrams during a manufacturing process using a method of manufacturing a display substrate according to another exemplary embodiment of the present disclosure.

The formation of the first sub-via hole and the second sub-via hole include: coating a first photoresist on a side of the passivation layer away from the base substrate: performing a full-exposure process on a first region of the photoresist corresponding to the first sub-via hole; etching a layer material in a region corresponding to the first sub-via hole to expose the first electrode: stripping the first photoresist: coating a second photoresist on a side of the passivation layer away from the base substrate, so that a part of the second photoresist is filled in the first sub-via hole: performing a full-exposure on a second photoresist region corresponding to the second sub-via hole: etching a layer material in a region corresponding to the second sub-via hole to expose the transfer portion, where the exposed transfer portion forms a via hole sidewall of the first electrode via hole: and stripping the second photoresist. For example, the first photoresist and the second photoresist may be the same photoresist.

A detailed description will be made below with reference to FIG. 9A to FIG. 9G. The aforementioned process is the same as the process of FIG. 8A to FIG. 8E.

As shown in FIG. 9A, after the passivation layer 60 is formed and the photoresist 80 is coated on the passivation layer 60, a full-exposure process is performed on a region of the first photoresist corresponding to the first sub-via hole, thus the region Q1 corresponding to the first sub-via hole may be determined.

As shown in FIG. 9B, the layer material in the region Q1 corresponding to the first sub-via hole is etched to expose the first electrode, for example, the passivation layer 60 and the gate insulating layer 101 are etched, so as to expose the first electrode in the first conductive layer 20.

As shown in FIG. 9C, the photoresist 80 is stripped.

As shown in FIG. 9D, the photoresist 80 is coated on the side of the passivation layer 60 away from the base substrate so that a part of the photoresist 80 is filled in the first sub-via hole.

As shown in FIG. 9E, a full-exposure process is performed on the region Q2 corresponding to the second sub-via hole, that is, the photoresist corresponding to the second sub-via hole region is exposed.

As shown in FIG. 9F, the layer material in the region Q2 corresponding to the second sub-via hole is etched to expose the transfer portion. The exposed transfer portion is configured to form the via hole sidewall of the first electrode via hole. For example, the passivation layer or the like is etched, thereby forming the second sub-via hole.

As shown in FIG. 9G, the photoresist 80 is stripped, so as to form the first electrode via hole VH1 which includes the first sub-via hole and the second sub-via hole.

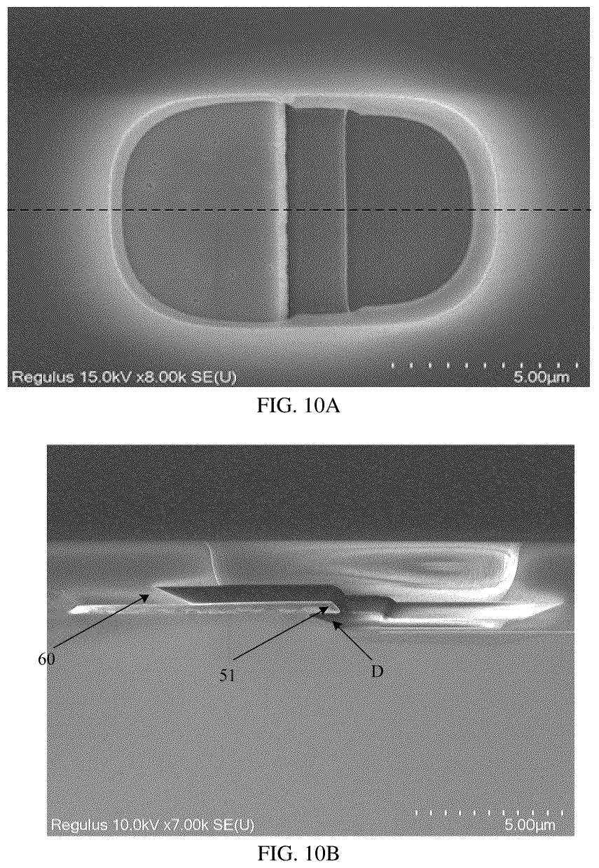

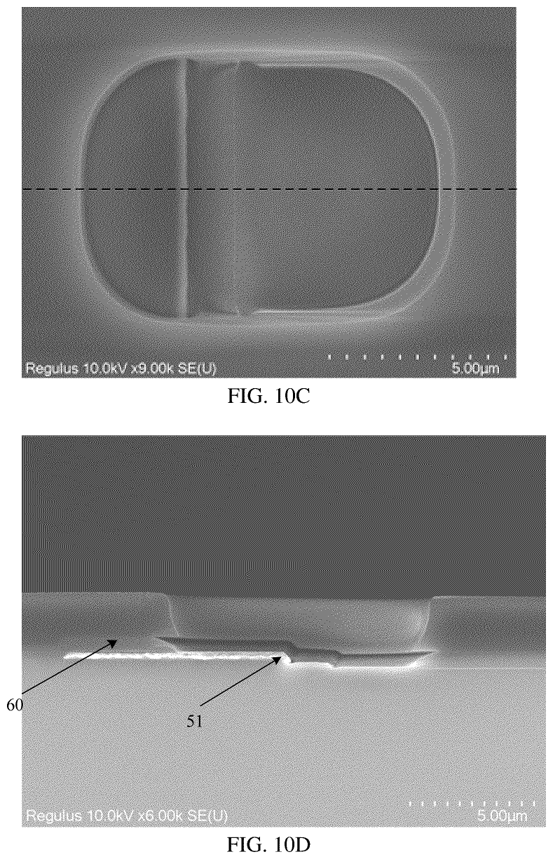

FIG. 10A is a schematic plan view of a first electrode via hole manufactured using a conventional manufacturing method. FIG. 10B is an actual cross-sectional structural diagram taken along the dashed line in FIG. 10A. FIG. 10C is a schematic plan view of a first electrode via hole manufactured using a manufacturing method according to an exemplary embodiment of the present disclosure. FIG. 10D is an actual cross-sectional structural diagram taken along the dashed line in FIG. 10C.

As shown in the actual cross-sectional structural diagram of the first electrode via hole manufactured by the conventional manufacturing method in FIG. 10A and FIG. 10B, during a formation process of the first electrode via hole using the conventional manufacturing method, a full-exposure process is performed on the region of the first electrode via hole, after the material of the passivation layer is etched, the transfer portion 51 in the third conductive layer arranged on the lower side of the passivation layer is exposed, and at this point, the first electrode is not exposed yet, so that the gate insulating layer needs to be etched. Since the exposed third conductive layer has an “antenna effect”, that is, an exposed metal of the transfer portion will attract plasma, resulting in an etching rate near the lower side of the transfer portion accelerating. Therefore, the gate insulating layer is over-etched on a lower side of the bottom of the transfer portion, so that the transfer portion 51 extends towards the first electrode via hole relative to the sidewall of the first electrode via hole to form a protrusion, and a void defect D is formed at the bottom, as shown in FIG. 10B. In addition, during the subsequent etching of the gate insulating layer on a side of the transfer portion close to the base substrate, the exposed transfer portion will be subjected to plasma bombardment for a long time, which may cause oxidation of its surface and thus is prone to poor contact. In a subsequent process, for example, when the photoresist on the surface of the passivation layer is stripped through a wet stripping process, the stripping liquid is likely to remain in the defect D, which may cause electrode via hole corrosion or poor connection, and reduce the yield of the product.

In contrast, in the method of manufacturing a display substrate according to the embodiments of the present disclosure, as shown in FIG. 10C and FIG. 10D, the exposed part of the transfer portion 51 in the third conductive layer by the first electrode via hole is configured to form the via hole sidewall of the first electrode via hole, and the transfer portion 51 does not protrude relative to the via hole sidewall, so that the opening area of the first electrode via hole gradually decreases in the direction pointing towards the base substrate. In this way, the defect D when using the conventional manufacturing method is not present in the first electrode via hole. Therefore, the oxidation caused by the prolonged plasma bombardment on the exposed transfer portion 51 is avoided. In addition, the electrode via hole corrosion caused by the defect D is also avoided, thereby effectively improving the product yield of the display substrate.

Another aspect of the present disclosure further provides a display apparatus including the display substrate described above, and the display substrate is manufactured using the manufacturing method described above.

Beneficial effects achieved by the display apparatus in the above-mentioned embodiments of the present disclosure are the same as the beneficial effects achieved by the above-mentioned display substrate, which will not be described in details here.

The above-mentioned display apparatus may be any apparatus that displays either images or texts, whether in motion (e.g., video) or stationary (e.g., still images). More specifically, it is expected that the embodiments described herein may be implemented in or associated with a variety of electronic apparatuses, such as (but not limited to) a mobile phone, a wireless device, a personal data assistant (PDA), a handheld or portable computer, a GPS receiver/navigator, a camera, a MP4 video player, a video camera, a game console, a watch, a clock, a calculator, a TV monitor, a flat panel display, a computer monitor, an automobile display (e.g., an odometer display, etc.), a navigator, a cockpit controller and/or display, a display of camera view (e.g., a display of a rearview camera in a vehicle), an electronic photo, an electronic billboard or indicator, a projector, an architectural structure, a packaging and aesthetic structure (e.g., a display of image of a piece of jewelry), etc.

Although some embodiments according to the general inventive concept of the present disclosure have been illustrated and described, those of ordinary skill in the art will understand that changes may be made to these embodiments without departing from the principle and spirit of the general inventive concept of the present disclosure, and the scope of the present disclosure is defined by the claims and their equivalents.

1. A display substrate, comprising:
a base substrate, wherein a plurality of sub-pixels are arranged on the base substrate in an array in a first direction and a second direction, the first direction intersects with the second direction, and each sub-pixel comprises at least one control transistor;
a first conductive layer arranged on a side of the base substrate, wherein the first conductive layer comprises first electrodes arranged at intervals in the second direction and configured to form the sub-pixel;
a second conductive layer arranged on a side of the first conductive layer away from the base substrate, wherein the second conductive layer comprises gate electrodes configured to form the control transistors, wherein the gate electrodes are arranged at intervals in the second direction and extend in the first direction;
a semiconductor layer arranged on a side of the second conductive layer away from the base substrate, wherein an orthographic projection of the semiconductor layer on the base substrate falls within an orthographic projection of the second conductive layer on the base substrate;
a third conductive layer arranged on a side of the semiconductor layer away from the base substrate, wherein the third conductive layer comprises a transfer portion, and an orthographic projection of the transfer portion on the base substrate falls within an orthographic projection of the first electrode on the base substrate;
a passivation layer arranged on a side of the third conductive layer away from the base substrate;
a first electrode via hole penetrating the passivation layer and exposing a part of the first electrode and a part of the transfer portion, wherein an opening area of the first electrode via hole gradually decreases in a direction pointing towards the base substrate, and the exposed part of the transfer portion serves as a part of a via hole sidewall of the first electrode via hole; and
a fourth conductive layer arranged in the first electrode via hole and electrically connecting the first electrode to the transfer portion.

2. The display substrate according to claim 1, wherein the via hole sidewall of the first electrode via hole comprises a step portion; and
the step portion comprises:
a step top surface, wherein an exposed surface of the transfer portion on a side away from the base substrate serves as the step top surface; and
a step side surface, wherein an exposed surface of the transfer portion facing an inside of the first electrode via hole serves as the step side surface,
wherein an opening area of the first electrode via hole at the step side surface is greater than or equal to an opening area of the first electrode via hole on a side of the step portion close to the base substrate.

3. The display substrate according to claim 2, wherein a surface roughness of an unexposed surface of the transfer portion on a side away from the base substrate is less than a surface roughness of the step top surface.

4. The display substrate according to claim 2, wherein an angle between the step top surface of the step portion and the step side surface of the step portion is θ, wherein 90°<θ<180°.

5. The display substrate according to claim 2, wherein the first electrode via hole exposes a part of the semiconductor layer, and the exposed part of the semiconductor layer serves as a part of the via hole sidewall of the first electrode via hole; and
an opening area of the first electrode via hole at the semiconductor layer is less than or equal to an opening area of the first electrode via hole at the step portion.

6. The display substrate according to claim 1, wherein
the first electrodes comprise pixel electrodes arranged at intervals in the first direction, wherein each pixel electrode corresponds to a respective sub-pixel; and
the third conductive layer further comprises:
data signal lines arranged at intervals in the first direction and extending in the second direction; and
a first electrode and a second electrode configured to form the control transistor,
wherein the first electrode of the control transistor is electrically connected to the data signal line, and the second electrode of the control transistor is electrically connected to the transfer portion.

7. The display substrate according to claim 6, wherein the third conductive layer further comprises voltage signal lines arranged at intervals in the first direction and extending in the second direction, wherein
the voltage signal line is arranged between adjacent data signal lines; and
the sub-pixel is arranged between voltage signal line and data signal line adjacent to each other.

8. The display substrate according to claim 7, wherein the voltage signal line is electrically connected to a common electrode through a second electrode via hole.

9. The display substrate according to claim 8, wherein
the gate electrode is arranged between adjacent pixel electrodes;
orthographic projections of the first electrode and the second electrode of the control transistor on the base substrate fall within the orthographic projection of the semiconductor layer on the base substrate, and the orthographic projection of the semiconductor layer on the base substrate falls within an orthographic projection of the gate electrode on the base substrate; and
the gate electrode is configured to control transmission of a data signal from the data signal line to the pixel electrode via the control transistor, the transfer portion and the fourth conductive layer.

10. The display substrate according to claim 9, wherein
the sub-pixels comprise a first sub-pixel and a second sub-pixel adjacent to each other in the first direction, the first sub-pixel and the second sub-pixel are arranged between adjacent data signal lines, and the voltage signal line is arranged between the first sub-pixel and the second sub-pixel;
the gate electrodes comprise a first gate electrode and a second gate electrode adjacent to each other in the second direction;
the first gate electrode is configured to control a control transistor of a first sub-pixel close to the first gate electrode; and
the second gate electrode is configured to control a control transistor of a second sub-pixel close to the second gate electrode.

11. The display substrate according to claim 1, wherein
the first electrodes comprise common electrodes, and a side of each common electrode away from the base substrate is provided with a plurality of first electrode via holes; and
the third conductive layer further comprises a connection portion, and the connection portion electrically connects transfer portions corresponding to common electrodes adjacent to each other in the second direction,
wherein the connection portion is configured to electrically connect the common electrodes adjacent to each other in the second direction through the fourth conductive layer arranged in the first electrode via hole and the transfer portion.

12. The display substrate according to claim 11, wherein
the second conductive layer further comprises voltage signal lines arranged at intervals in the second direction and extending in the first direction; and
the voltage signal line is electrically connected to the common electrode.

13. The display substrate according to claim 12, wherein
the gate electrode is arranged adjacent to the voltage signal line, and the gate electrode and the voltage signal line are arranged between adjacent common electrodes.

14. The display substrate according to claim 13, wherein
the third conductive layer further comprises:
data signal lines arranged at intervals in the first direction and extending in the second direction; and
a first electrode and a second electrode configured to form the control transistor;
wherein the first electrode of the control transistor is electrically connected to the data signal line, and the second electrode of the control transistor is electrically connected to a pixel electrode through a third electrode via hole.

15. A method of manufacturing a display substrate, comprising:
forming a first conductive layer on a side of a base substrate, wherein the first conductive layer comprises first electrodes arranged at intervals in a second direction and configured to form sub-pixels arranged on the base substrate, the sub-pixels arranged on the base substrate are arranged in an array in a first direction and the second direction, and the first direction intersects with the second direction;
forming a second conductive layer on a side of the first conductive layer away from the base substrate, wherein the second conductive layer comprises gate electrodes that are arranged at intervals in the second direction, extend in the first direction and are configured to form control transistors;
forming a semiconductor layer on a side of the second conductive layer away from the base substrate, wherein an orthographic projection of the semiconductor layer on the base substrate falls within an orthographic projection of the second conductive layer on the base substrate;
forming a third conductive layer on a side of the semiconductor layer away from the base substrate, wherein the third conductive layer comprises a transfer portion, and an orthographic projection of the transfer portion on the base substrate falls within an orthographic projection of the first electrode on the base substrate;
forming a passivation layer on a side of the third conductive layer away from the base substrate;
forming a first electrode via hole penetrating the passivation layer and exposing a part of the first electrode and a part of the transfer portion, wherein an opening area of the first electrode via hole gradually decreases in a direction pointing towards the base substrate, and the exposed part of the transfer portion serves as a part of a via hole sidewall of the first electrode via hole; and
forming a fourth conductive layer in the first electrode via hole, wherein the fourth conductive layer electrically connects the first electrode to the transfer portion.

16. The method according to claim 15, wherein
the forming a first electrode via hole comprises: forming a first sub-via hole and a second sub-via hole, wherein
the first sub-via hole exposes a part of the first electrode, and an orthographic projection of the first sub-via hole on the base substrate does not overlap with the orthographic projection of the transfer portion on the base substrate; and
the second sub-via hole exposes a part of the transfer portion, and an orthographic projection of the second sub-via hole on the base substrate overlaps with the orthographic projection of the transfer portion on the base substrate.

17. The method according to claim 16, wherein the forming a first sub-via hole and a second sub-via hole comprises:
coating a photoresist on a side of the passivation layer away from the base substrate;
performing a full-exposure process on a region of the photoresist corresponding to the first sub-via hole, and performing a half-exposure process on a region of the photoresist corresponding to the second sub-via hole;
etching a layer material in a region corresponding to the first sub-via hole to expose the first electrode; and
etching a layer material in a region corresponding to the second sub-via hole to expose the transfer portion,
wherein the exposed transfer portion is configured to form the via hole sidewall of the first electrode via hole.

18. The method according to claim 17, wherein the etching a layer material in a region corresponding to the first sub-via hole comprises:
etching a region of the passivation layer corresponding to the first sub-via hole, and etching a region of an insulating layer corresponding to the first sub-via hole with a first dry etching medium, wherein the insulating layer is between the passivation layer and the first electrode in the region;
wherein the etching a layer material in a region corresponding to the second sub-via hole comprises:
etching a material of the photoresist in a region of the second sub-via hole with a second dry etching medium; and
etching a material of the passivation layer in the region of the second sub-via hole with a first dry etching medium;
wherein the method further comprises: etching a photoresist arranged on an upper side of the passivation layer with a second dry etching medium.

19. (canceled)

20. (canceled)

21. The method according to claim 16, wherein
the forming a first sub-via hole and forming a second sub-via hole comprises:
coating a first photoresist on a side of the passivation layer away from the base substrate;
performing a full-exposure process on a region of the first photoresist corresponding to the first sub-via hole;
etching a layer material in a region corresponding to the first sub-via hole to expose the first electrode;
stripping the first photoresist;
coating a second photoresist on a side of the passivation layer away from the base substrate so that a part of the second photoresist is filled in the first sub-via hole;
performing a full-exposure process on a region of second photoresist corresponding to the second sub-via hole;
etching a layer material in a region corresponding to the second sub-via hole to expose the transfer portion, wherein the exposed transfer portion is configured to form the via hole sidewall of the first electrode via hole; and
stripping the second photoresist.

22. A display apparatus comprising a display substrate according to claim 1.
